(19) United States
(12) Patent Application Publication
(10) Pub. No.: US 2026/0314330 A1
(43) Pub. Date: Oct. 8, 2026

(54) SUBSTRATE CHUCKING ASSIST MODULE

(71) Applicant: Applied Materials, Inc., Santa Clara, CA (US)

(72) Inventors: Pavan Bommajjara Puttaswamy, Bangalore (IN); Preston Fung, Daly City, CA (US); Cheuk Ming Lee, Castro Valley, CA (US); David M. Corriveau, Sacramento, CA (US); Vasuman Ghanapaati Srirangarajan, Bangalore (IN); Benjamin Johnston, Los Gatos, CA (US)

(21) Appl. No.: 19/479,977

(22) PCT Filed: May 9, 2024
(86) PCT No.: PCT/US2024/028643

§ 371 Date: Oct. 29, 2025

Related U.S. Application Data
(60) Provisional application No. 63/466,061, filed on May 12, 2023.

(51) Int. Cl. H10P 72/76; H10P 72/00; H10P 72/78

(52) U.S. Cl. CPC H10P 72/7618; H10P 72/0428; H10P 72/78

(57) ABSTRACT

Advanced packaging systems are disclosed for securing a substrate to a movable stage for processing. In some embodiments, a substrate pushing unit may be provided comprising a pushing assembly and linear actuator, wherein the linear actuator may lower the pushing assembly onto the substrate to apply a downward force to flatten the substrate.

### TECHNICAL FIELD

The present disclosure generally relates to the field of semiconductor device manufacturing and more particularly to systems, methods, and apparatuses for securing a substrate in advanced packaging systems.

### BACKGROUND

Due to an ever-increasing demand for miniaturized electronic devices and components, integrated circuits have evolved into complex 2D, 2.5D, and 3D devices that can include millions of transistors, capacitors, and resistors on a single chip. The evolution of chip design has resulted in greater circuit density to improve the processing capability and speed of integrated circuits. The demand for faster processing capabilities with greater circuit densities imposes corresponding demands on the materials, structures, and processes used in the fabrication of integrated circuit packages. Alongside these trends toward greater integration and performance, however, there exists the perpetual pursuit for reduced manufacturing costs.

### BRIEF DESCRIPTION OF THE DRAWINGS

The disclosure will be understood more fully from the detailed description below and from the accompanying drawings of various embodiments of the disclosure. The drawings are notably illustrative in nature and should not be taken to limit the disclosure to specific embodiments. Instead, they should be considered broadly for the explanation and teachings that they may provide.

FIG. 1A illustrates a perspective view of an advanced packaging system in accordance with at least one embodiment of the present disclosure.

FIG. 1B illustrates a side view of the advanced packaging system of FIG. 1A with a substrate pushing unit in a fully raised position.

FIG. 1C illustrates a perspective view of a chuck of the advanced packaging system of FIG. 1A in accordance with at least one embodiment of the present disclosure.

FIG. 1D illustrates a perspective view of a lift pin structure and lift pin actuators of the advanced packaging system of FIG. 1A in accordance with at least one embodiment of the present disclosure.

FIGS. 1E-1F illustrate a side view of a portion of the advanced packaging system of FIG. 1A with a substrate pushing unit in a fully raised and a fully lowered position.

FIG. 2A illustrates a perspective view of a substrate pushing unit in accordance with at least one embodiment of the present disclosure.

FIG. 2B illustrates a cross-sectional view of a portion of the substrate pushing unit of FIG. 2A along a first plane.

FIG. 2C illustrates a cross-sectional view of another portion of the substrate pushing unit of FIG. 2A along a first plane.

FIG. 3A illustrates a perspective view of another advanced packaging system in accordance with at least one embodiment of the present disclosure.

FIG. 3B illustrates a side view of the advanced packaging system of FIG. 3A with a substrate pushing unit in a fully raised position.

FIG. 3C illustrates a top view of a chuck of the advanced packaging system of FIG. 3A in accordance with at least one embodiment of the present disclosure.

FIG. 3D illustrates a perspective view of a lift pin structure and lift pin actuator of the advanced packaging system of FIG. 3A in accordance with at least one embodiment of the present disclosure.

FIG. 3E illustrates a side cross-sectional view of a chuck of the advanced packaging system of FIG. 3A in accordance with at least one embodiment of the present disclosure.

FIG. 3F illustrates a side view of a portion of the advanced packaging system of FIG. 3A with a substrate pushing unit in a fully raised position.

FIG. 4A illustrates a perspective view of another substrate pushing unit in accordance with at least one embodiment of the present disclosure.

FIG. 4B illustrates a cross-sectional view of a portion of the substrate pushing unit of FIG. 4A along a first plane.

FIG. 5 illustrates a top, bottom, and side view of a rectangular substrate in accordance with at least one embodiment of the present disclosure.

FIG. 6 illustrates a top, bottom, and side view of a round substrate in accordance with at least one embodiment of the present disclosure.

FIG. 7 illustrates side views of a pair of warped substrates in accordance with at least one embodiment of the present disclosure.

FIG. 8 illustrates a flow diagram of an example method for receiving and securing a substrate to a stage for processing in accordance with at least one embodiment of the present disclosure.

FIG. 9 illustrates a block diagram of an example computer system in accordance with at least one embodiment of the present disclosure.

### DETAILED DESCRIPTION

The present disclosure generally relates to the field of semiconductor device manufacturing and more particularly to systems, methods, and apparatuses for securing a substrate in advanced packaging systems. A number of advanced packaging (AP) technologies have emerged to meet current demands, including a variety of different wafer level packaging (WLP) and panel level packaging (PLP) techniques. Manufacturing systems that employ such techniques will typically secure a wafer or panel substrate to a high-precision movable stage for processing (e.g., to perform a microlithography process thereon). The substrate, for example, may be secured using a chucking mechanism, such as a vacuum chuck, that may operate to pull the substrate downward and secure it onto the stage.

In some cases, however, the substrate may not be entirely flat (e.g., due to warpage from previous processing and/or handling) such that securing the substrate using a chucking mechanism alone is practically infeasible. For example, in order to vacuum chuck a highly warped panel substrate (e.g., exhibiting 6 mm or more of warpage), a significant amount of air flow (e.g., in excess of 700 L² /min) would be needed (i.e., to flatten and secure the substrate). Existing chucking mechanisms are unable to produce these high flow rates and would need to be modified in order to do so. Producing these high flow rates, for instance, would require a large number of additional pneumatic lines to be drawn to the processing stage. But doing so would adversely affect stage performance, for example, by impacting the precision of its movement (e.g., on account of a tension placed on the stage by the pneumatic lines pulling). Furthermore, this high flow capability is only used for a brief period of time (i.e., during securement) and only needed in the substrate loading/unloading area, such that modifying the system in this way-which is itself a non-trivial undertaking-would not be worth the benefits it would provide, particularly at the expense of stage performance.

Embodiments of the present disclosure address the above-mentioned challenges by employing a substrate pushing unit that includes a pushing assembly positioned above a processing stage that can be lowered onto a substrate provided thereon to apply a downward pushing force to a top surface of the substrate. The downward pushing force applied by the pushing assembly may help to flatten the substrate allowing it to be secured to the processing stage (e.g., by existing chucking mechanisms). In this way, the need for complex modifications to the chucking mechanism of a packaging system (e.g., to include additional pneumatic lines) is obviated, allowing warped substrates to be secured to the processing stage without sacrificing stage performance.

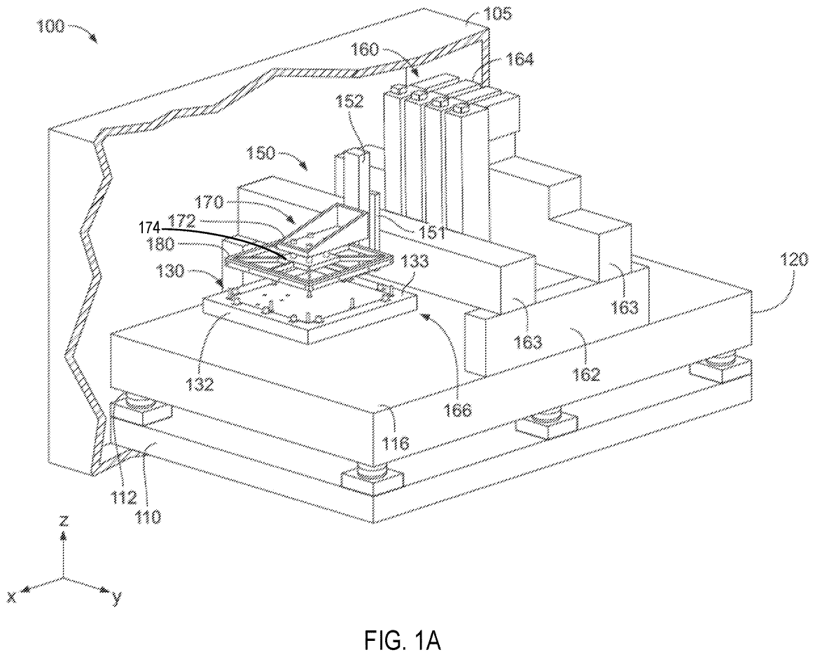

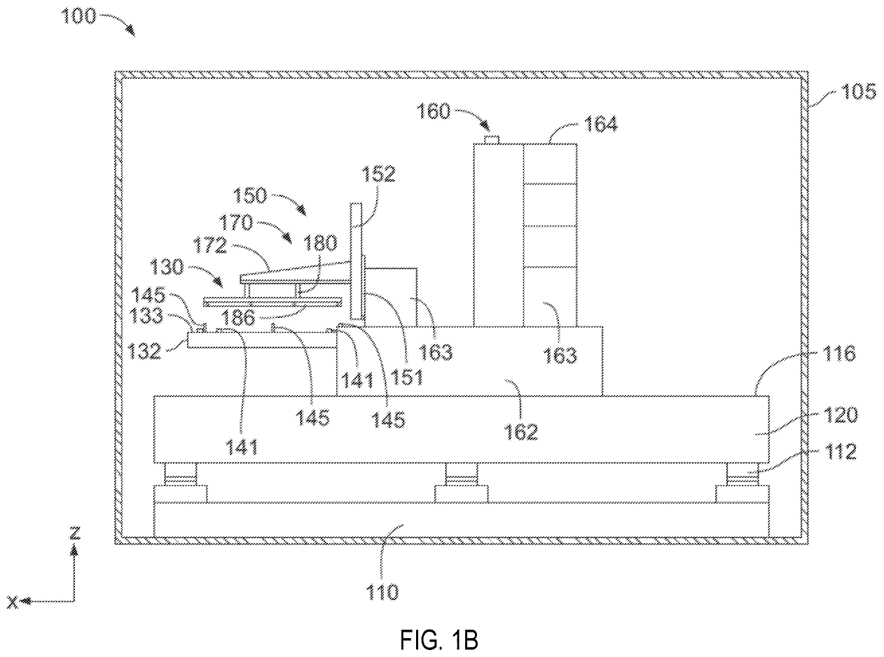

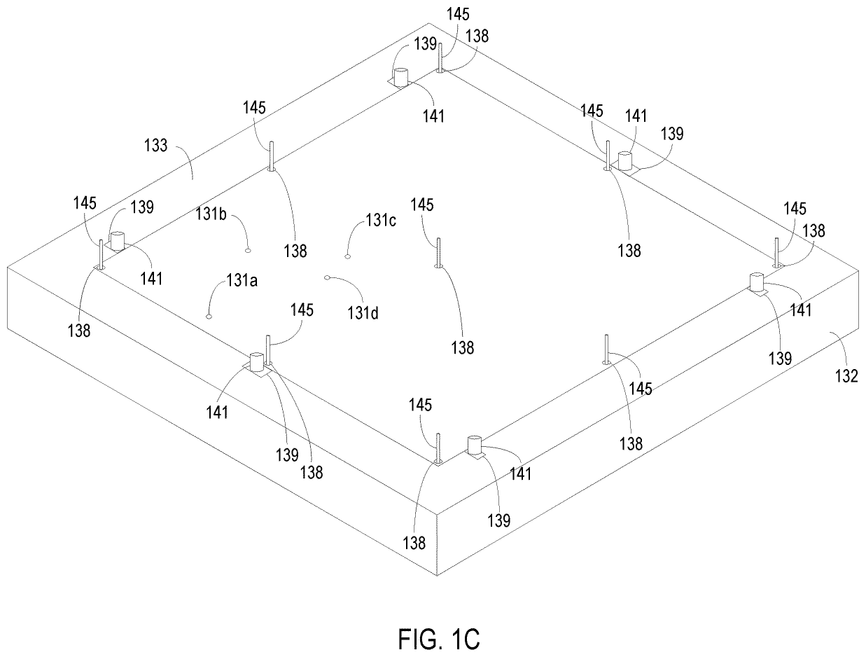

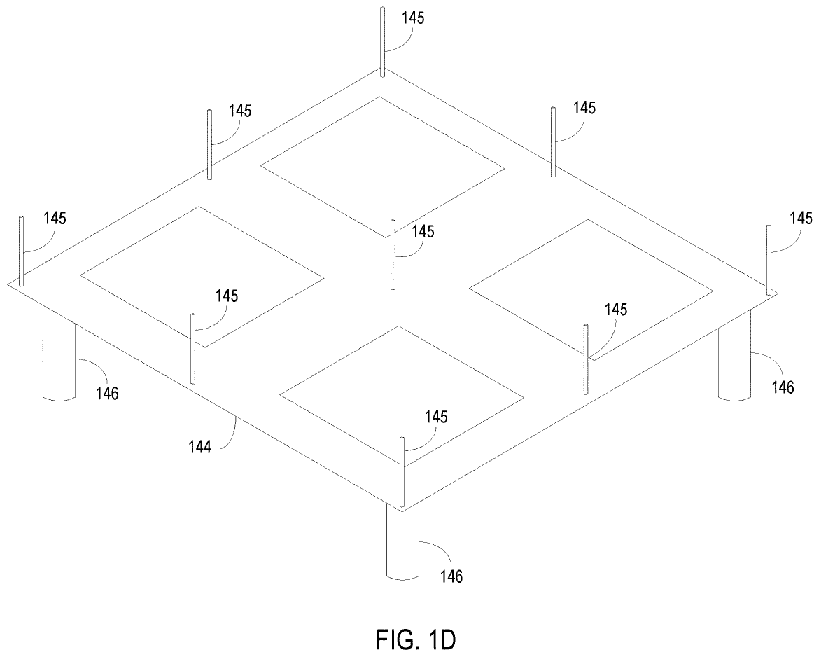

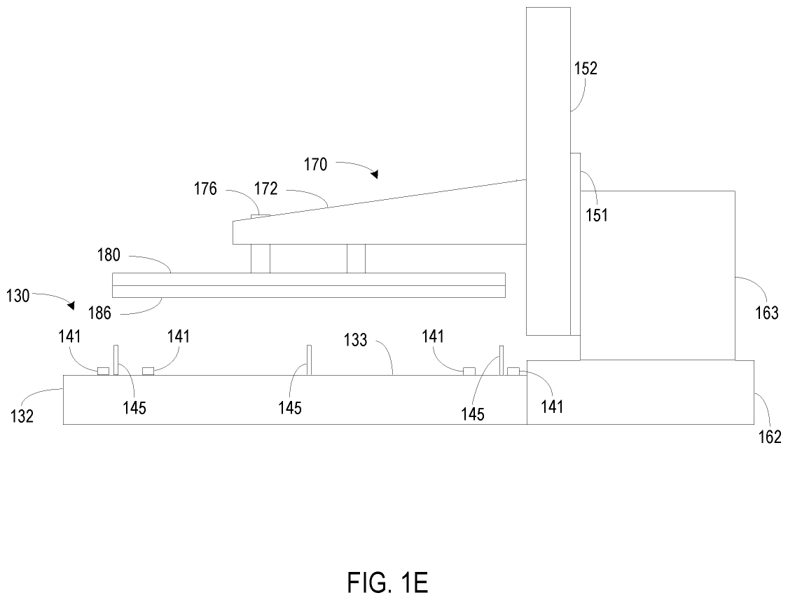

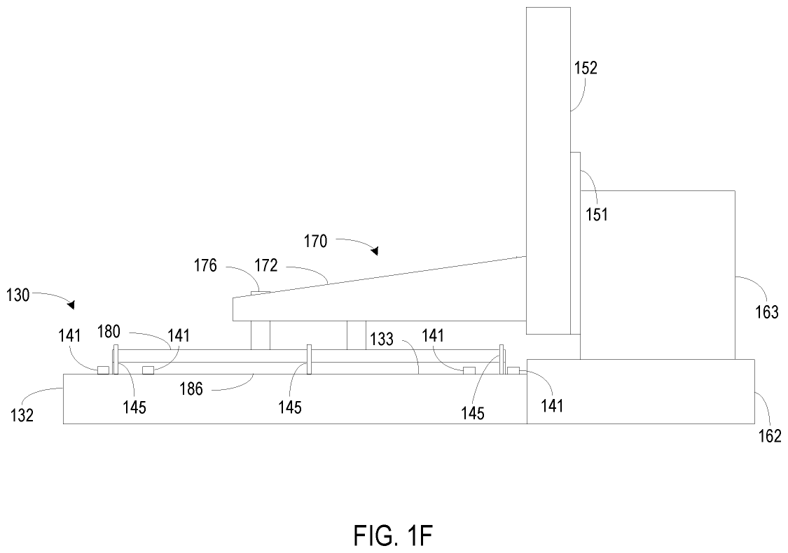

FIGS. 1A-1F (collectively FIG. 1) illustrate various views of an advanced packaging system 100 for processing a substrate (not shown in FIG. 1) in accordance with at least one embodiment of the present disclosure. Advanced packaging system 100 may include a base frame 110, a slab 120, a stage 130, and a processing apparatus 160, which may be enclosed within a processing chamber formed by enclosure 105. Stage 130 may be adapted to receive one or more substrates (e.g., from a robot or end effector (not shown in FIG. 1)) and secure the substrates for processing (e.g., to a chuck 132 of stage 130). In some cases, a substrate may not be entirely flat (e.g., due to warpage from previous processing and/or handling) and may be secured with the assistance of a substrate pushing unit 150. Once secured, the substrate may be moved under processing apparatus 160 for processing. Additional detail regarding advanced packaging system 100 and its components is provided below.

A substrate may take a variety of forms (e.g., varying in material, size, shape, weight, etc.) depending on the embodiment and its application. In some embodiments, for example, a substrate may be a wafer or panel made of quartz, silicon, or glass (e.g., borosilicate glass), plastic, or other suitable material for electronic device formation. In some embodiments, a substrate may have a photoresist layer formed on its surface (e.g., a top and/or bottom surface), on which a pattern forming photolithography process may be performed.

In some embodiments (e.g., as in FIG. 1), a substrate may be a rectangular substrate (e.g., a substrate panel, glass carrier panel, glass core panel, etc.) having a particular length and width (e.g., 510 mm×515 mm, 650 mm×550 mm, etc.), thickness (e.g., between 200 μm and 3.5 mm), and weight (e.g., between 100 g and 3.5 kg). In other embodiments, a substrate may be a round or disk-shaped substrate (e.g., a silicon wafer, glass carrier wafer, etc.) having a particular diameter (e.g., up to 300 mm) and thickness (e.g., between 500 μm and 1.7 mm). Advanced packaging system 100 may handle a number of different substrates during operation. In some embodiments, for example, advanced packaging system 100 may handle substrates having a same or similar shape and dimension (e.g., 510 mm×515 mm rectangular substrates, or 300 mm round substrates) but with varying thicknesses.

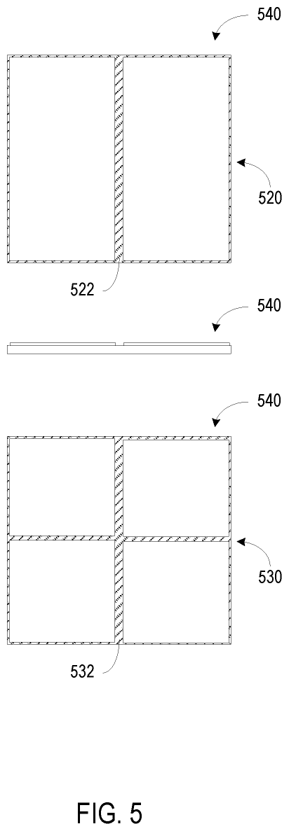

In some embodiments, a substrate may have one or more areas (e.g., on a top and/or bottom surface) that are suitable for handling and/or contact (e.g., that are not being employed to create electrical features). Such areas may be referred to as exclusion areas or edge exclusion areas. By way of example, FIG. 5 illustrates a rectangular substrate 540 having a top surface 520 and a bottom surface 530. Top surface 520 may be suitable for contact in regions 522 (depicted with cross-hatching), which may include a narrow region (e.g., 6 mm in width) around the perimeter of top surface 520 as well as a narrow region (e.g., 10 mm in width) along its center vertically. Bottom surface 530, in turn, may be suitable for contact and handling in regions 532 (depicted with cross-hatching), which may include a narrow region (e.g., 10 mm in width) around the perimeter of bottom surface 530 as well as a narrow region (e.g., 10 mm in width) along its center vertically and a narrow region (e.g., 7.5 mm in width) along its center horizontally.

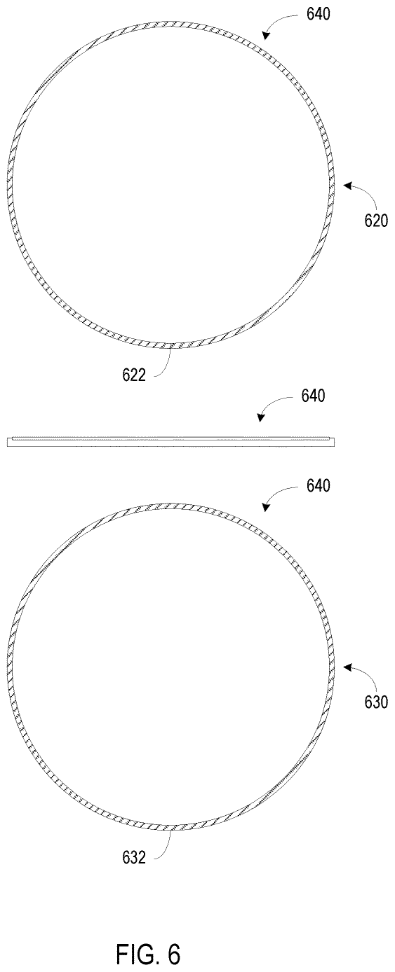

As another example, FIG. 6 illustrates a round substrate 640 having a top surface 620 and a bottom surface 630. Top surface 620 may be suitable for contact in region 622 (depicted with cross-hatching), which may include a narrow region (e.g., 3 mm in width) around the perimeter of top surface 620. Bottom surface 630, in turn, may be suitable for contact and handling in regions 632 (depicted with cross-hatching), which may include a narrow region (e.g., 3 mm in width) around the perimeter of bottom surface 630. In some embodiments, substrate 640 may have a beveled edge (e.g., a chamfer or radial fillet edge) along its circumference (not shown in FIG. 6), for example, extending beyond regions 622 and 632.

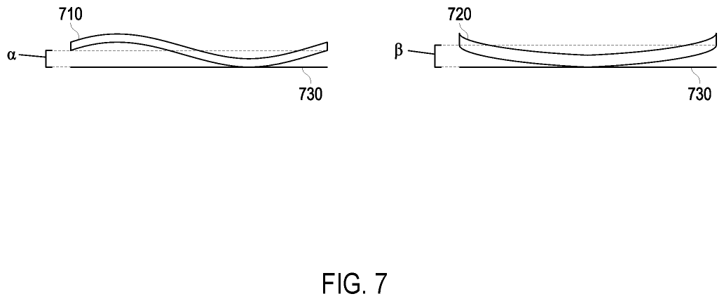

Substrates may be generally flat in nature but may exhibit some amount of variation in flatness across their surface (e.g., variations in a Z direction relative to an X and/or Y dimension). Substrates, for example, may be warped to varying degrees (e.g., on account of prior processing and/or handling). A substrate, for instance, may exhibit some amount of concavity or convexity and/or have wave like variations across its surface. In some embodiments, an amount of variation in the flatness of a substrate (e.g., an amount of warpage) may be specified in terms of a largest distance between a bottom side of the substrate and a top surface of an object on which the substrate may be disposed (e.g., a top surface of chuck 132 of stage 130 on which a substrate may be received). By way of example, FIG. 7 illustrates side views of a pair of warped substrates 710 and 720 commonly disposed on a surface 730. Warped substrate 710 exhibits a slight concavity and has an amount of warpage of a. Warped substrate 720 exhibits wave like variations and has an amount of warpage of ß. Advanced packaging system 100 may be adapted to handle substrates having varying amounts of flatness variation (or warpage) (e.g., up to 20 mm of warpage).

Enclosure 105 may be adapted to control a processing environment for processing a substrate. In some embodiments, for example, enclosure 105 may be a safety enclosure adapted to control the temperature, pressure, humidity, and/or other environmental parameters of the chamber within enclosure 105 in which base frame 110, slab 120, stage 130 (and any substrates thereon), substrate pushing unit 150, and processing apparatus 160 may be housed. In some embodiments, enclosure 105 may also operate to maintain the processing chamber in a clean state, for example, by capturing and exhausting debris particles from there within (e.g., that may be produced during processing and/or handling of a substrate).

Base frame 110 may rest on the floor of a fabrication facility and may support slab 120, which may be a monolithic structure such as a large piece of granite or stone. Base frame 110 and slab 120 may provide a rigid and stable base on which stage 130 and processing apparatus 160 may be disposed. In some embodiments, active and/or passive air isolators 112 may be positioned between base frame 110 and slab 120 and may operate to provide vibration isolation and improve slab stability.

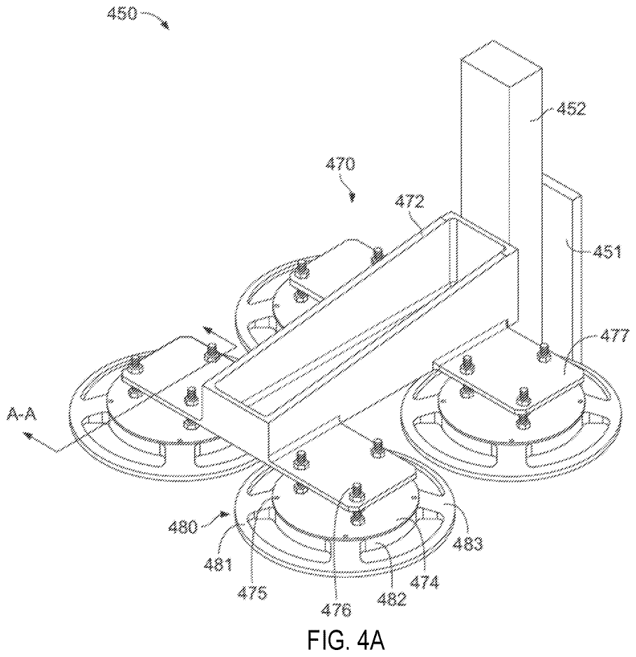

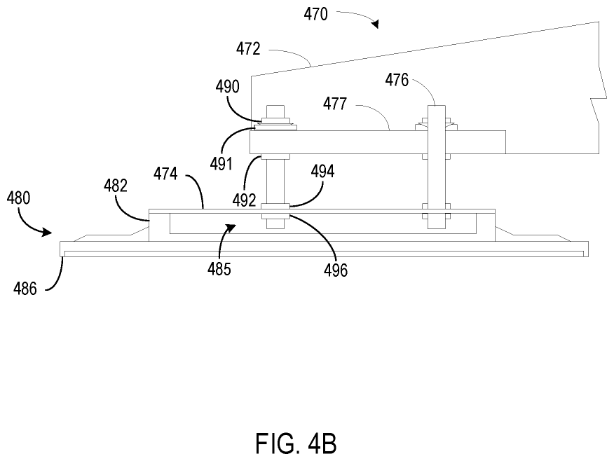

Stage 130 may be movably disposed on slab 120 and adapted to receive and secure a substrate for processing (e.g., by processing unit 164 of processing apparatus 160). While FIG. 1 illustrates a single stage 130, advanced packaging system 100 may include fewer or more stages in other embodiments and may be adapted to receive and secure multiple substrates for processing (e.g., as in the embodiment of FIG. 4).

In some embodiments, for example, advanced packaging system 100 may include one or more drive systems that may provide for independent positioning and movement of stage 130 (e.g., in an X, Y, and/or Z direction relative to slab 120). In some embodiments, the drive systems may provide for high-precision positioning and/or movement of stage 130 (e.g., at a micro or nano scale). In some embodiments, for instance, advanced packaging system 100 may include a linear drive system that can move stage 130 independently in the X direction (or an X drive system) and a linear drive system that can move stage 130 independently in the Y direction (or a Y drive system). In some embodiments, for example, an X drive system and a Y drive system may comprise one or more linear motors (e.g., cylindrical, U-channel, or flat type linear motors) to control movement of stage 130 (e.g., to a particular position at a desired velocity and/or rate of acceleration).

In some embodiments, for instance, an X drive system may include one or more forcers (e.g., having wire coils provided therein) that may move along one or more corresponding magnetic tracks, which may be disposed on a top surface 116 of slab 120 and oriented in the X direction. In some embodiments, for example, a pair of forcers may be coupled to opposite sides of a first support body of stage 130 (not shown in FIG. 1), such as a carriage or a slide. In this way, movement of the forcers along the magnetic tracks may affect movement of the first support body (and stage 130) in the X direction relative to top surface 116 of slab 120. A Y drive system, similarly, may include one or more forcers (e.g., having wire coils provided therein) that may move along on one or more corresponding magnetic tracks, which may be disposed on a top surface of the first support body and oriented in the Y direction. In some embodiments, for example, a forcer may be coupled to a second support body of stage 130 (not shown in FIG. 1), such as a carriage or slide. In this way, movement of the first support body may affect movement of the second support body in the X direction, and movement of forcers of the Y drive system along its corresponding magnetic track may affect movement of the second support body in the Y direction (i.e., relative to a top surface of the first support body and top surface 116 of slab 120). In some embodiments, advanced packaging system 100 may include one or more bearings (not shown in FIG. 1) to facilitate movement of stage 130. In some embodiments, for instance, system 100 may include air bearings disposed between the first support body and top surface 116 of slab 120 and air bearings disposed between the second support body and top surface 116 of slab 120 that may provide pressurized air to levitate stage 130 during movement.

During operation, stage 130 may move from a home position (or a load/unload position), where stage 130 may be accessible (e.g., to a robot or end effector), to a processing position wherein stage 130 may pass under processing apparatus 160 and processing unit 164 thereof. It will be appreciated that a processing position may refer to one or more positions of stage 130 under processing apparatus 160 and/or processing unit 164. Likewise, a home position (or load/unload position) may be any position of stage 130 that is clear of the processing apparatus 160 and/or where stage 130 may be accessible (e.g., by a robot or end effector).

During operation, after a substrate has been loaded onto stage 130 (e.g., at a home position), stage 130 may be lifted (in the Z direction) by air bearings disposed between stage 130 and the planar surface 116 of the slab 120. An X drive system may be actuated to move stage 130 in the X direction into opening 166 of support 162. In some embodiments, a Y drive system may be used to move stage 130 laterally relative to support 162 (i.e., in the Y direction) while stage 130 is disposed within opening 166. Air bearings may be used to provide frictionless movement of stage 130 in either of the X and Y directions. The movement of the stage 130, actuation of the air bearings, as well as control of the processing unit 164 may be provided by a controller (as discussed below).

In some embodiments, one or more encoders, sensors, and/or accelerometers may be used to provide positional information (and optionally velocity and/or acceleration information). In some embodiments, for example, an encoder may be coupled to stage 130 that may determine a position (and optionally a velocity and/or acceleration) of the stage, and any substrate thereon, which may be provided to a controller (not shown in FIG. 1). In some embodiments, for instance, an encoder may be an optical encoder. In some cases, an actual position of stage 130 and the position measured by an encoder may differ. In some embodiments, a plurality of interferometers (not shown in FIG. 1) may be used in order to more accurately measure the position of stage 130 and any substrate thereon. In some embodiments, a more accurate position measurement may be provided by one or more additional sensors. In some embodiments, for example, a plurality of interferometers (not shown in FIG. 1) may be disposed on slab 120 and aligned with mirrors (not shown in FIG. 1) coupled to stage 130. The mirrors may be positioned closer to a substrate than the encoder, and thus may provide a more accurate position measurement. A number of different types of interferometers may be used depending on the embodiment and its application. In some embodiments, for example, high stability plane mirror (HSPM) interferometers may be used. The positional information measured by the interferometers may be provided to the controller (not shown in FIG. 1).

As noted above, stage 130 may be adapted to receive and secure substrate for processing. In some embodiments, for example, stage 130 may include a chuck 132 on which substrate may be received. Chuck 132 may be coupled atop (or integrally formed as part of) a second support body of stage 130. The form of chuck 132 (e.g., material size, shape, etc.) may vary depending on the embodiment and its application (e.g., depending on the shape and size of substrates that may be received). In some embodiments, for example, chuck 132 may be made of the same material as the second support body, such as aluminum. In some embodiments, chuck 132 may be made of (or coated with) a different material, such as silicon or a ceramic material, which may help to reduce backside contamination of a substrate. In some embodiments, chuck 132 may be rectangular in form, while in others, chuck 132 may be round or disk-shaped. In some embodiments, chuck 132 may have a surface area of approximately 1 square meter, though larger or smaller chucks may be suitable for other embodiments and applications.

In some embodiments, stage 130 may include a plurality of lift pins 145 and clamp pins 141 that may be used to receive and position a substrate on chuck 132 (e.g., as illustrated in FIGS. 1C-1E). In some embodiments, for example, chuck 132 may have a plurality of clearance holes 138 formed therethrough, which may be sized and shaped so as to accommodate lift pins 145 therein, and may have a plurality of slots 139 formed therethrough, which may be sized and shaped so as to accommodate and permit movement of clamp pins 141 therein. In some embodiments, lift pins 145 may be coupled to (or integrally formed as part of) a lift pin structure 144 disposed within a second support body, which may be coupled to one or more lift pin actuators 146 that may operate to move lift pin structure 144 (and lift pins 145) in the Z direction (i.e., through corresponding clearance holes 138). Lift pin actuators 146, for example, may operate to move lift pin structure 144 from an initial position, where lift pins 145 are fully recessed below a top surface 133 of chuck 132 and/or within a second support body, to a final position, where lift pins 145 are fully raised (i.e., through clearance holes 138 and beyond top surface 133 of chuck 132).

Lift pins 145 may be appropriately positioned and of sufficient length to facilitate substrate transfer by a robot or end effector (e.g., providing adequate space between lift pins 145 and between top surface 133 of chuck 132 and a lower surface of a substrate that may rest there upon). The robot or end effector, for instance, may provide substrates through a port (not shown in FIG. 1) in enclosure 105 and may position substrate on raised lift pins 145 (e.g., after moving lift pin actuator 146 to a final position). Lift pins 145 may thereafter gently lower the substrate onto chuck 132 (e.g., by moving lift pin actuators 146 to an initial position).

When a substrate is initially received on chuck 132 (e.g., from the robot or end effector), it may not be in the exact position desired for processing (e.g., which may benefit from the substrate being consistently positioned on chuck 132). In some embodiments, stage 130 may include a plurality of clamp pins 141 that may help to receive and reposition substrate on chuck 132 to a desired position before it is secured for processing. Clamp pins 141 may be made of or covered with a material suitable for contacting substrate (e.g., nonmarring, producing minimal debris particles, etc.). In some embodiments, for example, an engineered thermoplastic may be used, such as polyetheretherketone (PEEK), polyphenylene sulfide (PPS), or other high-performance semicrystalline thermoplastic. In some embodiments, a subset of the plurality of clamp pins 141 may serve as banking clamp pins (or reference clamp pins) that may help receive a substrate (e.g., by a robot or end effector), for example, by serving as a bank or reference against which a substrate may be placed. In some embodiments, another subset of the plurality of clamp pins 141 may serve as pushing clamp pins that may reposition the substrate once received. In some cases, a clamp pin 141 may serve as both a banking clamp pin and a pushing clamp pin.

In some embodiments, clamp pins 141 may be coupled to (or integrally formed as part of) a clamp structure (not shown in FIG. 1) disposed within the second support body, which may be coupled to one or more clamp actuators (not shown in FIG. 1) that may operate to move the clamp structure and clamp pins 141 in the Z direction (i.e., through corresponding slots 139). The clamp actuators, for example, may operate to move the clamp structure from an initial position, where clamp pins 141 are fully recessed below a top surface 133 of chuck 132 and/or within the second support body, to a final position, where clamp pins 141 are fully raised (i.e., through slots 139 and beyond top surface 133 of chuck 132). In some embodiments, the clamp actuators (or a portion thereof) may also operate to move the clamp structure and clamp pins 141 medially (e.g., in an X and/or Y direction or a radial direction), for example, from an initial outer position to a final inner position.

In some embodiments, for example, during operation, clamp actuators may raise a first subset of clamp pins 141 that serve as banking clamps from a fully recessed to a fully raised position, after which a substrate may be received on chuck 132 (e.g., from a robot or end effector). Clamp actuators may then raise a second subset of clamp pins 141 from a fully recessed to a fully raised position. Once raised, clamp actuators may move the second subset of clamp pins 141 (and in some cases, a portion of the first subset of clamp pins 141 that also serve as pushing clamps) medially, within slots 139, from an initial outer position to a final inner position, repositioning the substrate in the process (i.e., to a desired X-Y position on chuck 132). Once repositioned, the substrate may be secured to chuck 132 (as discussed below) and clamp actuators may operate to move pushing clamp pins 141 back to their outer position and may lower clamp pins 141 back to a fully recessed position.

In some embodiments, stage 130 may include a mechanism to secure substrates thereto (e.g., to chuck 132). In some embodiments, for example, stage 130 may include a chucking mechanism (e.g., a vacuum chucking mechanism, an electrostatic chucking mechanism, or the like) that may operate to apply a downward pulling force on a substrate and secure it to chuck 132. In some embodiments, for example, a vacuum chucking mechanism may include a vacuum source (not shown in FIG. 1) that may be in fluid communication with one or more ports or apertures 131 formed in chuck 132. The vacuum source may operate to pull air through apertures 131, which may apply a downward pulling force on a substrate pulling it toward chuck 132 and secure it thereto. The pulling force may draw the substrate into contact with apertures 131, such that once the substrate is secured, air may no longer flow through apertures 131 and a vacuum pressure may drop.

In some embodiments, the vacuum chucking mechanism may provide for different chucking zones. In some embodiments, for example, the vacuum source may be able to pull air through apertures 131 independently and may operate to pull air through a subset of one or more apertures 131 to provide different chucking zones. For example, as illustrated in FIG. 1, each of apertures 131a-d may provide for four separate chucking zones. In some embodiments, each a chucking zone may be further segmented into a number of different zones, for example, an outer and inner zone.

As noted above, a substrate may exhibit some amount of warpage (or other variations in its flatness), in which case the downward pulling force may operate to flatten the substrate. The amount of force required to flatten a substrate may depend on the amount of substrate warpage. In some cases, where a substrate exhibits a significant amount of variation (e.g., a significant amount of warpage), the downward pulling force produced by the chucking mechanism (e.g., vacuum chuck) alone may not be sufficient to flatten the substrate. In such cases, a substrate pushing unit 150 may be used to apply a downward pushing force to help flatten the substrate (as discussed in further detail below).

In some embodiments, the vacuum source may also be able to push air (e.g., compressed dry air) through apertures 131 (e.g., at a relatively low flow rate) and may operate to do so when moving a substrate (e.g., during loading/unloading or repositioning of substrate) in order to lift the substrate off chuck 132 and reduce any interaction between the substrate and chuck 132, which could produce debris particles and/or damage the substrate. In some embodiments, one or more additional apertures may be provided in chuck 132 and/or a separate vacuum source may be used for such purposes. It will be appreciated that advanced packaging system 100 may include a number of elements not shown in FIG. 1 in order to provide for fluid communication between apertures 131 and a vacuum source and facilitate the flow of air therethrough, including for example, one or more pneumatic tubes, lines, pumps, valves, regulators, filters, manifolds, or the like.

In some embodiments, stage 130 may include one or more sensors that may provide information that is used during processing of a substrate. In some embodiments, for example, stage 130 may include one or more substrate presence sensors (e.g., an optical sensor) that may be able to detect the presence of a substrate on a top surface 133 of chuck 132. In some embodiments, for instance, the substrate presence sensors may be disposed within chuck 132 (and/or a second support body), which may include one or more slots in its top surface 133 through which the optical sensors may be able to detect the presence of a substrate.

In some embodiments, advanced packaging system 100 may also include a cable management system (not shown in FIG. 1) to manage the different cables and lines (e.g., electrical power lines, pneumatic lines, control lines, etc.) used by stage 130. In some embodiments, for example, the cables and lines utilized by stage 130 may be coupled to one or more cable carriers that may move alongside stage 130 (e.g., in at least one direction). In some embodiments, for example, the cable management system may include cable carriers coupled to the first support body and/or second support body.

Processing apparatus 160 may comprise a support 162 (e.g., disposed on slab 120) and a processing unit 164 secured thereto for processing substrates. In some embodiments, for example, support 162 may be a gantry structure having a plurality of bridges 163 that span slab 120 (e.g., in the Y direction) and provide an opening 166 thereunder. Processing unit 164 may be secured to bridges 163 and disposed above opening 166, which may be suitably sized to permit stage 130 to pass under processing unit 164 and allow processing unit 164 to operate on any substrates provided thereon.

In some embodiments, for example, processing unit 164 may be a pattern generator configured to expose a photoresist disposed on a substrate to a photolithography process. Processing unit 164, for instance, may be a pattern generator configured to perform a maskless lithography process. In some embodiments, processing unit 164 may include one or more image projection systems disposed in a housing that may direct one or more light sources onto specific areas of a photoresist (e.g., as a substrate passes under the processing apparatus 160). The image projection systems, for example, may be part of a digital light projector device that utilizes laser light. In some embodiments, multiple laser light sources may be combined and projected onto a digital micro-mirror (e.g., a multi-faceted mirror) that redirects the light onto specific areas of the photoresist.

Substrate pushing unit 150 may be disposed above stage 130 used to help secure a substrate thereto. For example, in instances where a substrate is warped, substrate pushing unit 150 may be used to apply a downward pushing force to the substrate to help flatten the substrate and allow for its securement to stage 130 (e.g., using a vacuuming chuck).

In some embodiments, for example, substrate pushing unit 150 may be secured to support 162 of processing apparatus 160, which may provide a stable and rigid support for substrate pushing unit 150 and allow substrate pushing unit 150 to be positioned above stage 130 with minimal impact on stage accessibility (e.g., by a robot or end effector). In some embodiments, for instance, a bridge connecting plate 151 may be used to secure substrate pushing unit 150 to a bridge 163 of support 162. Bridge connecting plate 151, for instance, may be used to rigidly couple linear actuator 152 to a outer lateral surface (e.g., in the X direction) of a bridge 163 such that substrate pushing unit 150 may be disposed over stage 130 when in a load/unload position.

Linear actuator 152 may support a push assembly 170, which may be coupled thereto, and may operate to move push assembly 170 in a Z direction (e.g., relative to stage 130). Linear actuator 152, for example, may be able to move push assembly 170 from a retracted or fully raised position (e.g., as depicted in FIG. 1E) to a fully lowered position (e.g., as depicted in FIG. 1F). Push assembly 170 may be placed in a fully raised position when not in use. In the fully raised position, adequate space may be provided between a bottom of push assembly 170 and chuck 132 to permit loading/unloading of a substrate thereto/therefrom (e.g., by a robot or end effector). Because push assembly 170 may be suspended when not in use, push assembly 170 may be designed so as to minimize vibration when stationary (e.g., having a first modal frequency above 100Hz and/or a magnitude of no more than 5um). In this way, push assembly 170 may not unduly interfere with (e.g., introduce vibration into) system 100 when performing other processing operations (e.g., microlithography processing performed by processing unit 164).

Linear actuator 152 may lower push assembly 170 (e.g., from a fully raised position) when assistance with securement of a substrate is desired. In some embodiments, for example, linear actuator 152 may initiate lowering of push assembly 170 based upon a determination that an initial attempt at securing a substrate was unsuccessful and that assistance is needed. For instance, where a vacuum chucking mechanism is being used, a determination that an initial attempt was unsuccessful may be made based on feedback provided by a vacuum source (e.g., a vacuum pressure and/or air flow rate). For example, a determination that an initial attempt was unsuccessful may be made if a vacuum pressure does not drop (e.g., below a threshold amount) or if an air flow rate is high (e.g., above a threshold leakage amount) for an extended period of time, as this may indicate that a substrate has not been successfully drawn into contact with apertures 131 of chuck 132.

As pushing assembly 170 is lowered, it may be brought into contact with and apply a downward pushing force onto a substrate. In the fully lowered position, the substrate may be flattened and secured to chuck 132. Once secured, linear actuator 152 may return pushing assembly 170 to a fully raised position. In some embodiments, for example, linear actuator 152 may initiate return of pushing assembly 170 based upon a determination that the substrate was successfully secured to chuck 132. For instance, where a vacuum chucking mechanism is being used, a determination that the substrate was successfully secured may be made based on feedback provided by a vacuum source (e.g., based on an observed drop in vacuum pressure and/or a de minimis air flow rate).

In order to minimize a processing time of a substrate, linear actuator 152 may operate to move pushing assembly 170 (e.g., between a fully raised position to a fully lowered position and back) as quickly as possible. For example, in performing a downside or upside move, linear actuator 152 may accelerate as quickly as possible to reach a set speed (e.g., a maximum speed of linear actuator 152), move at the set speed for as long as possible, and decelerate as quickly as possible (e.g., to arrive at a final position). In some embodiments, linear actuator 152 may limit a speed at which pushing assembly 170 may travel when approaching a substrate (e.g., in a downside move), so as to minimize an impact when it is brought into contact with the substrate and avoid producing debris particles and/or damaging the substrate.

A number of different types of linear actuators 152 (e.g., stepper or servomotor driven ball screw or belt actuators) may be used depending on the embodiment and its application. A suitable linear actuator 152, for example, may be selected based on a number of different parameters, including a workload capacity (e.g., a maximum weight of pushing assembly 170 that can be supported), speed (e.g., a maximum speed at which pushing assembly 170 can be moved), positioning repeatability (e.g., a precision with which pushing assembly 170 can be moved), and/or clean room class (e.g., a maximum number of particles that may be produced). In some embodiments, for instance, linear actuator 152 may be a Class-10 linear actuator that includes a rotary servo (or stepper) driven motor, which drives a ball screw actuator, and has a workload capacity of 20 Kg, maximum speed of 1200 mm/s, and a positioning repeatability of ±0.02 mm.

Pushing assembly 170 may be used to apply a downward pushing force onto a substrate (e.g., as pushing assembly 170 is lowered by linear actuator 152). In some embodiments, for example, pushing assembly 170 may include a push frame 180 adapted to apply the downward pushing force onto a substrate. In some embodiments, for example, push frame 180 may have a contact pad 186 provided thereon that may contact a substrate to apply the downward pushing force.

The form of push frame 180 and contact pad 186 (e.g., material, size, shape, etc.) may vary depending on the embodiment and its application (e.g., depending on the shape and size of the substrates being secured). In some embodiments, for example, push frame 180 may be made of aluminum or other suitable material (e.g., light weight, inexpensive, etc.), and contact pad 186 may be made of or coated with a material suitable for contacting a substrate (e.g., nonmarring, producing minimal debris particles, etc.). In some embodiments, for example, contact pad 186 may be made of (or coated with) an engineered thermoplastic, such as polyetheretherketone (PEEK), polyphenylene sulfide (PPS), or other high-performance semicrystalline thermoplastic.

Push frame 180 may have a similar shape and size as a substrate being secured, such that push frame 180 may apply a generally uniform force to the substrate. Push frame 180 may also be shaped and sized so as to generally overlap with areas of a substrate that are suitable for contact and/or handling when positioned over the substrate. In some embodiments, push frame 180 may include one or more cavities through which air may flow, which may help to reduce the impact that push frame 180 may have on air circulation within enclosure 105. By way of example, with reference to substrate 540 of FIG. 5, push frame 180 may be generally rectangular in form and may comprise an outer ring portion connected to a central portion by a plurality of arms. When positioned over substrate 540, the outer ring portion and a subset of the arms may be disposed generally above handling and/or contact regions 522 and 532 of substrate 540.

Contact pad 186 may be coupled to push frame 180 and may be shaped and sized so as to align with areas of a substrate that are suitable for handling and/or contact. In some embodiments, for example, contact pad 186 may be a relatively thin (e.g., having a thickness of 5-6 mm in the X-Y plane) rectangular ring that when coupled to push frame 180 may align with a perimeter of a substrate, which may be suitable for contact and/or handling.

In some embodiments, push frame 180 may be flexibly and adjustably coupled to linear actuator 152. In some embodiments, for example, actuator bracket 172 may be secured to linear actuator 152 and may cantilever over stage 130. Actuator bracket 172, in turn, may be coupled to a flexure 174. In some embodiments, for example, actuator bracket 172 may be coupled to flexure 174 by a plurality of adjustment studs 176. Adjustments studs 176 may be individually and/or collectively adjusted to control an orientation (e.g., a pitch, yaw, and or roll) of push frame 180 relative to chuck 132 of stage 130. In this way, a motion axis of push frame 180 (e.g., as pushing assembly 170 is lowered) may be aligned perpendicular to chuck 132 so as to apply a uniform pushing force to a substrate provided thereon.

Flexure 174 may be secured to a top surface of a central portion of push frame 180 (e.g., by a plurality of screws spaced around its perimeter) and may provide for some degree of flexibility in push frame 180 relative to linear actuator 152. For example, as push frame 180 is pushed down on a substrate, flexure 174 may bulge or flex slightly and provide a degree of compliance in a Z direction (e.g., up to 200 μm). The compliance afforded by flexure 174 may help to accommodate variations in substrate warpage and/or thickness and prevent the application of excessive force to a substrate. In some embodiments, for example, flexure 174 may be a thin stainless-steel plate (e.g., a 17-4 precipitation hardened martensitic stainless-steel) that may be removably secured to push frame 180 (e.g., by a plurality of screws spaced around its perimeter).

In some embodiments, substrate pushing unit 150 may include one or more encoders, position sensors, and/or accelerometers in order to determine a position (and optionally a velocity and/or acceleration) of pushing assembly 170, which may be used to control its movement. In some embodiments, for example, the information provided by the encoders, sensors, and/or accelerometers may be used to precisely control movement of pushing assembly 170 (and push frame 180), including initiating a speed reduction of pushing assembly 170 prior to contact with a substrate (e.g., in a downside move), and/or determine if push frame 180 is out of alignment (e.g., having a motion axis misaligned with chuck 132). In some embodiments, for example, an encoder may be provided on a motor of linear actuator 152 (e.g., a rotary encoder on a servomotor thereof) to determine a position (and optionally a velocity and/or acceleration) of pushing assembly 170 (e.g., relative to linear actuator 152). In some embodiments, an encoder may additionally (or alternatively) may be provided on the actuator of linear actuator 152 (e.g., a linear encoder on a ball screw or belt) to determine a position of pushing assembly 170 (e.g., relative to linear actuator 152), which may be relatively more accurate than the encoder provided on the motor. In some embodiments, one or more position sensors (e.g., interferometers and corresponding mirrors) and/or accelerometers may additionally (or alternatively) be provided on push frame 180 to determine a position (and optionally a velocity and/or acceleration) of push frame 180 (e.g., relative to a top surface of a substrate). In some cases, these positions sensors may provide a more accurate measurement of the position of push frame 180 (and contact pad 186).

In some embodiments, substrate pushing unit 150 may include one or more force feedback sensors that may measure a force applied by substrate pushing unit 150 (e.g., by push frame 180 and contact pad 186) to a substrate. In some embodiments, the information provided by the force feedback sensors may be used to control linear actuator 152 to control the amount of force applied to the substrate through pushing assembly 170, which may help to minimize the likelihood of damage to the substrate.

In some embodiments, substrate pushing unit 150 may include a cleaning unit for clearing debris from the surface 133 of chuck 132. For example, during processing of a substrate, debris particles (e.g., dry film resist) may be deposited on chuck 132. When a subsequent substrate is placed on the chuck 132, the debris particles may cause a substrate to be raised in that region (i.e., where the debris particular is located), which may result in the substrate being improperly processed or prevent the substrate from being properly processed. Instead of manually cleaning the surface 133 of chuck 132, the cleaning unit may operate to automatically clear such debris.

In some embodiments, for example, one or more vacuum slots may be coupled to (e.g., mounted to) or integrally formed as part of push frame 180. The vacuum slots may be coupled to and in fluid communication with a vacuum source, which may operate to pull air through the vacuum slots that may provide a suction force in a localized region (e.g., around the vacuum slot opening) that may pull the debris particles off of the surface 133 of chuck 132 and carry them away. In some embodiments, the debris particles may be carried to and caught by a filter (e.g., in the communication path between the vacuum source and vacuum slots), where they may be collected for proper disposal. For example, during operation, the substrate pushing unit 150 may lower push assembly 170 such that push frame 180 is placed in close proximity with the surface 133 of chuck 132. The vacuum source may then operate to pull air through the vacuum slots and remove any debris particles from the chuck 132 surface 133. In some embodiments, stage 130 may be moved while the push frame 180 is in the lower position and the vacuum source is active in order to clean the entire chuck 132 surface 133 (or a desired region thereof). In some cases, the suction force provided by the vacuum source may not be sufficient to dislodge debris particles from the chuck 132 surface 133, and in some embodiments, an air knife may be coupled to (e.g., mounted to) push frame 180 that may operate to expel gas (e.g., compressed dry air) to help dislodge the debris particles. In some embodiments, for example, the air knife may expel CO₂ gas.

In some embodiments, the cleaning unit may also include a particle inspection device, which may be used to inspect certain debris particles (e.g., large debris particles over a threshold size). In some embodiments, for example, a particle inspection device may be coupled to (e.g., mounted to) push frame 180 that may operate to image debris particles on the surface 133 of chuck 132 (e.g., using a grazing incident laser illumination device and/or technique).

System 100 may also include a controller (not shown in FIG. 1) that may facilitate the control and operation of the components described herein to perform the processing techniques described. In some embodiments, for example, the controller may be coupled to or in communication with stage 130, substrate pushing unit 150, and processing apparatus 160, for controlling the operation thereof. The controller, for example, may control the position and movement of stage 130 (e.g., through control of an X drive system and a Y drive system), control the position and movement of pushing assembly 170 of substrate pushing unit 150 (e.g., through control of linear actuator 152), and control processing unit 164 of processing apparatus 160 (e.g., to perform a microlithography process on a photoresist provided on a substrate). The controller may also be in communication with various sensors and/or encoders of system 100, which for example, may provide information regarding a position and movement of stage 130 and substrate pushing unit 150 (or components thereof), operational information regarding a chucking mechanism (e.g., air pressure and/or air flow feedback from a vacuum source used for vacuum chucking). The controller may process the information provided by the sensors and/or encoders to control the operation of system 100 and its components (e.g., of stage 130, substrate pushing unit 150, and processing apparatus 160).

The controller may include a central processing unit (CPU) (not shown in FIG. 1 in FIG. 1), memory (not shown in FIG. 1), and support circuits (or I/O) (not shown in FIG. 1). The CPU may be one of any form of computer processors that are used in industrial settings for controlling various processes and hardware (e.g., pattern generators, motors, and other hardware) and monitor the processes (e.g., processing time and substrate position). The memory may be connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits may also be connected to the CPU for supporting the processor. The support circuits, for example, may include one or more caches, power supplies, clock circuits, input/output circuitry, subsystems, and the like. A program (or computer instructions) readable by the controller may determine which tasks are to be performed on a substrate. The program may be software readable by the controller and may include code to monitor and control, for example, the processing time and substrate position.

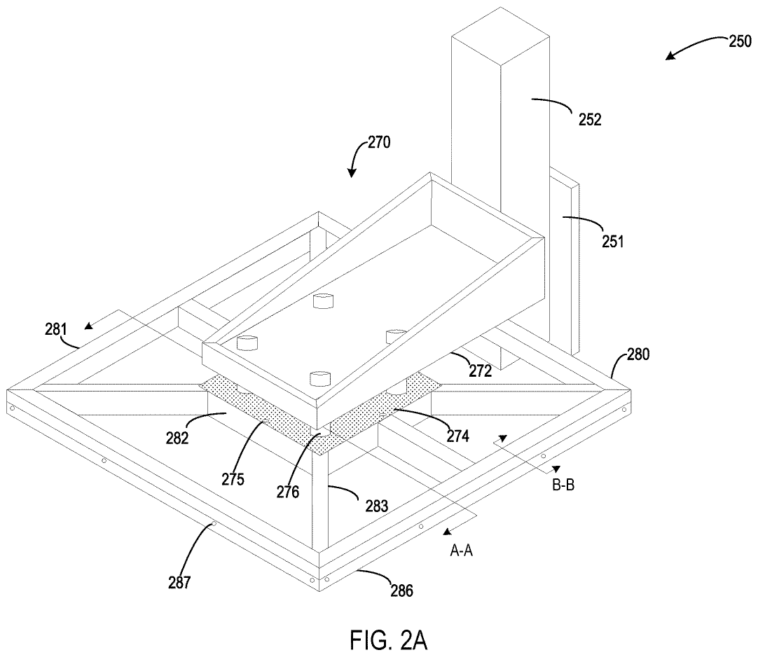

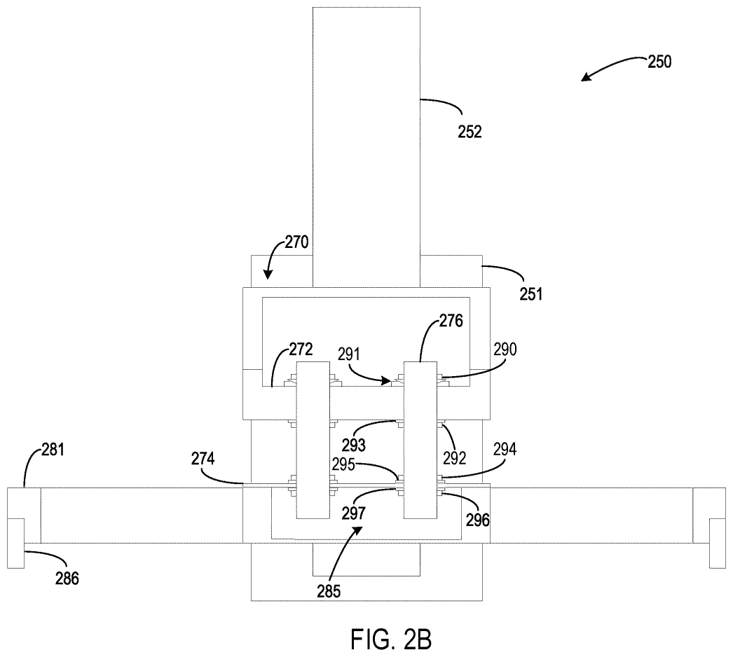

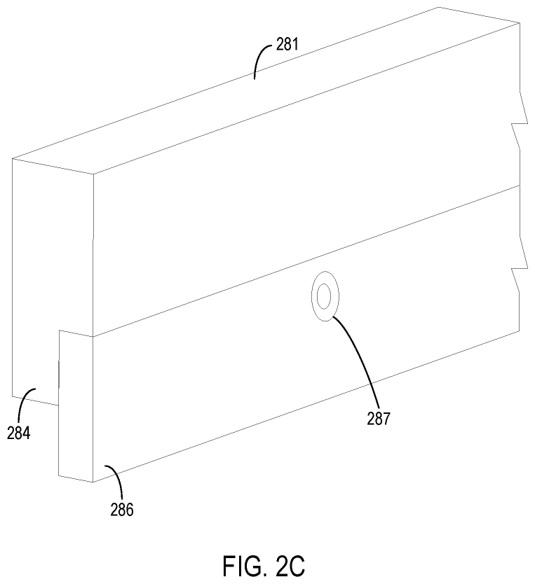

FIGS. 2A-2C (collectively FIG. 2) illustrate a substrate pushing unit 250 in accordance with at least one embodiment of the present disclosure. In some embodiments, substrate pushing unit 250 may serve as the substrate pushing unit 150 in the advanced packaging system 100 of FIG. 1. As illustrated, pushing unit 250 may include a connecting plate 251, which may be used to secure substrate pushing unit 250 to a support structure, and a linear actuator 252, which may support a pushing assembly 270 coupled thereto and operate to move pushing assembly 270 in a Z direction. Pushing assembly 270 may include a push frame 280, having a contact pad 286 provided thereon, that may be shaped and sized similar to a substrate (not shown) being secured, such that push frame 280 may apply a generally uniform force thereon. Push frame 280 may be generally rectangular in form and may comprise an outer ring portion 281 connected to a central portion 282 by a plurality of arms 283.

Push frame 280 may be flexibly and adjustably coupled to linear actuator 252 using flexure 274 and actuator bracket 272. In some embodiments, for example, actuator bracket 272 may be coupled to flexure 274 by a plurality of adjustment studs 276. Each adjustment stud 276, for instance, may be secured at a proximal end to actuator bracket 272 and at a distal end to flexure 274 (e.g., as shown in FIG. 2B). In some embodiments, for example, adjustment studs 276 may pass through corresponding clearance holes (or slots) provided in actuator bracket 272 and may be secured to actuator bracket 272 by a pair of nuts 290 and 292. Likewise, in some embodiments, adjustment studs 276 may pass through corresponding clearance holes (or slots) provided in flexure 274 and be secured to flexure 274 by a pair of nuts 294 and 296. In some embodiments, a spherical float 291 may be provided between nut 290 and a top surface of base of actuator bracket 272 and a washer 293 may be provided between nut 292 and a bottom surface of base actuator bracket 272. Likewise, in some embodiments, a pair of washers 295 and 297 may be provided between nuts 294 and 296 and a top and bottom surface of flexure 274. Adjustments studs 276 may be individually adjustable (e.g., providing adjustment in a Z direction) and/or collectively adjustable (e.g., with respect to the clearance holes) to control an orientation (e.g., a pitch, yaw, and or roll) of push frame 280. In that regard, spherical floats 291 may provide for some amount of compliance when adjusting an orientation of the push frame.

Flexure 274 may be secured to push frame 280. In some embodiments, for example, flexure 274 may be secured to push frame 280 at central portion 282 (e.g., by a plurality of screws 275 spaced around its perimeter). In some embodiments, a cavity 285 may be provided in central portion 282 in order to accommodate nuts 296 below a bottom surface of flexure 274, as depicted in FIG. 2B. Flexure 274 may provide for some degree of flexibility in push frame 280 relative to linear actuator 252. For example, as a push frame 280 is pushed down onto a substrate (not shown), flexure 274 may bulge or flex slightly and provide a degree of compliance in a Z direction (e.g., up to 200 μm). The compliance afforded by flexure 274 may help to accommodate variations in substrate warpage and/or thickness and prevent the application of excessive force to a substrate.

Contact pad 286 may be coupled to push frame 280 and may be shaped and sized so as to align with areas of a substrate (not shown) that are suitable for handling and/or contact. In some embodiments, for example, contact pad 286 may be a relatively thin (e.g., having a thickness of 5-6 mm in the X-Y plane) rectangular ring that when coupled to push frame 280 may align with a perimeter of a substrate, which may be suitable for contact and/or handling. By way of example, with reference to substrate 540 of FIG. 5, push frame 280 may be provided with a flange 284 along a perimeter of its bottom surface, as illustrated in FIG. 2C. Contact pad 286 may be removably coupled to flange 284, for example, using a plurality of screws 287. In some embodiments, contact pad 286 may be provided with slotted holes that may accommodate screws 287 and allow for fine grained adjustment (e.g., relative to adjustment via adjustment studs 276) of an orientation of pad 286 as they are secured to flange 284. A portion of contact pad 286 may extend beyond flange 284 and establish a bottom surface of pushing assembly 170 that may be brought into contact with substrate 540. Contact pad 286, for instance, may interface with the portions of handling and/or contact regions 522 and 532 around the perimeter of top and bottom surfaces 520 and 530, respectively. In some embodiments, push frame 280 may also include a flange along arms of its vertical center (not shown) and a contact pad may be coupled thereto. The vertical bar may interface with handling and/or contact regions 522 and 532 along the vertical center of substrate 540. In this way, a downward pushing force may be more uniformly distributed across the top and/or bottom surface of substrate 540.

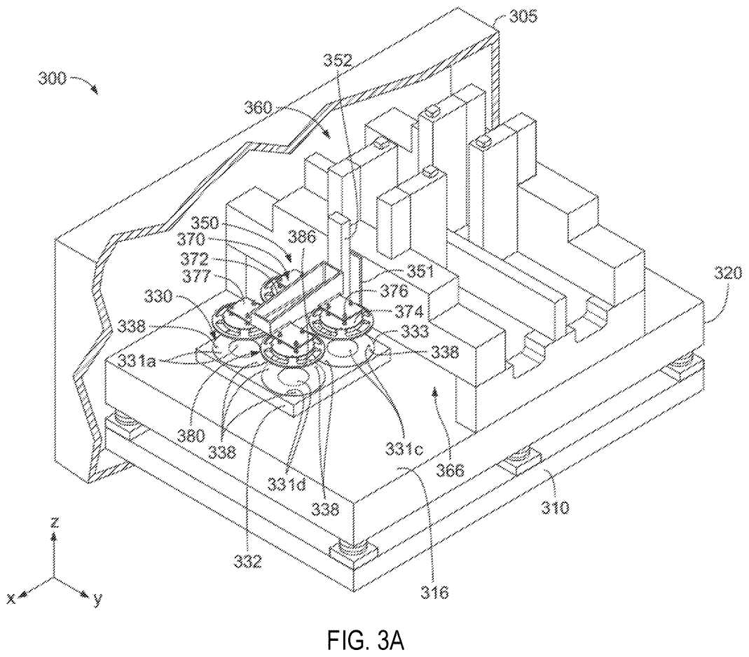

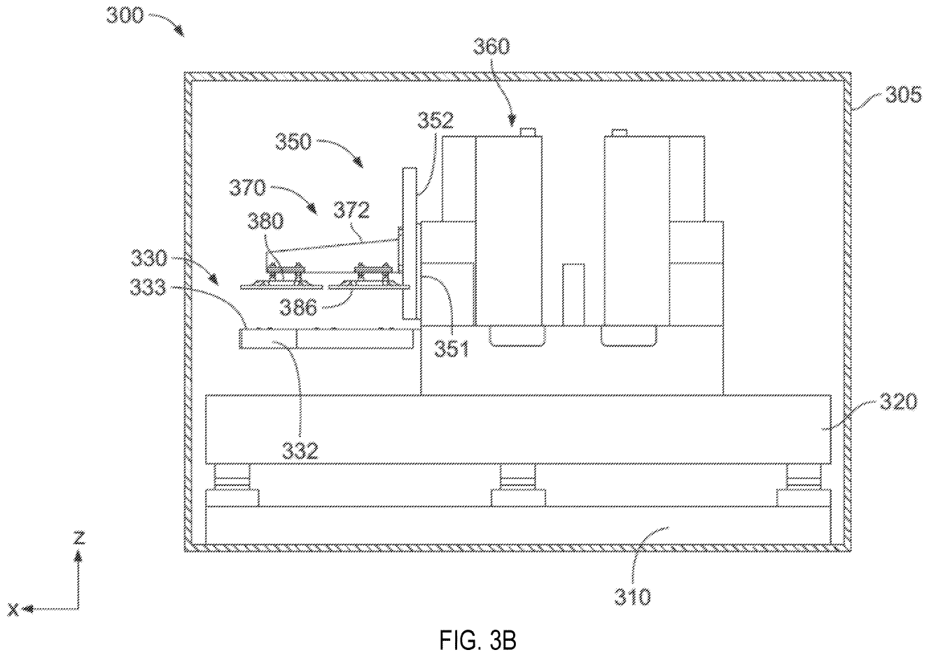

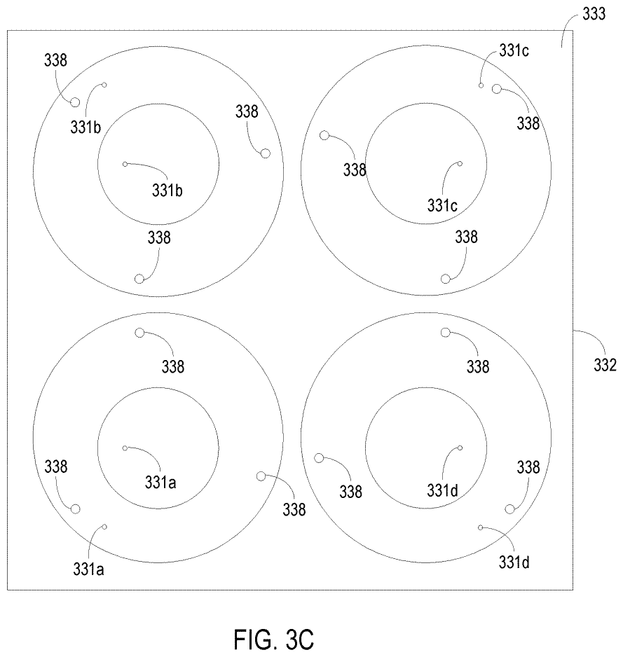

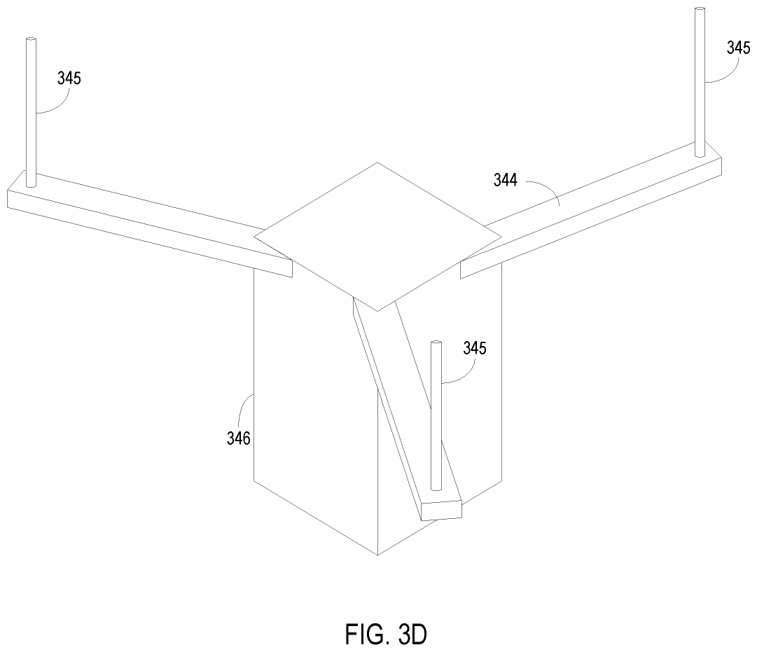

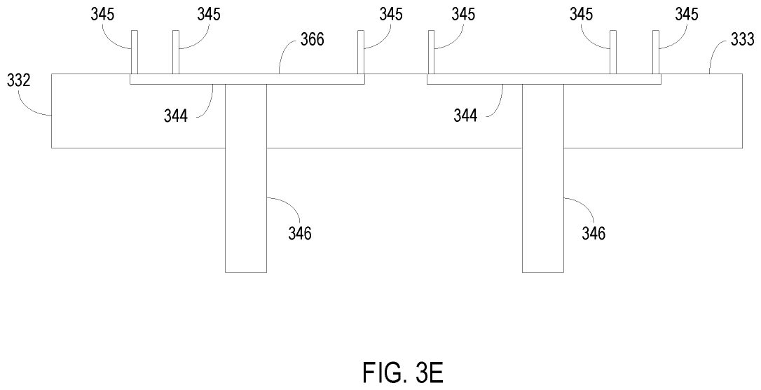

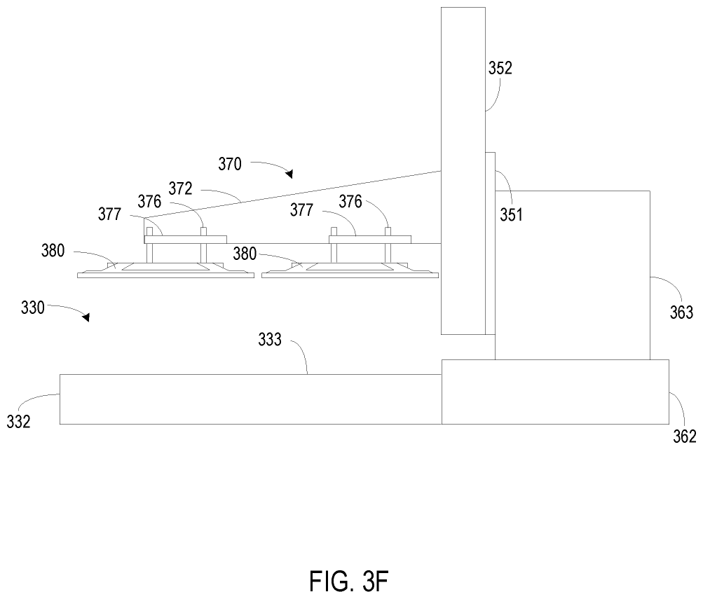

FIGS. 3A-3E (collectively FIG. 3) illustrate an advanced packaging system 300 in accordance with at least one embodiment of the present disclosure. Advanced packaging system 300 is similar to the advanced packaging system 100 of FIG. 1 but is adapted to collectively process a plurality of substrates. As illustrated, advanced packaging system 300 may include a base frame 310, a slab 320, a stage 330, and a processing apparatus 360, which may be enclosed within a processing chamber formed by enclosure 305. Stage 330 may be adapted to receive a plurality of substrates (e.g., from a robot or end effector (not shown in FIG. 3)) and secure the substrates for processing (e.g., to a chuck 332 of stage 330). In some cases, the substrates may not be entirely flat (e.g., due to warpage from previous processing and/or handling) and may be secured with the assistance of a substrate pushing unit 350. Once secured, the substrates may be moved under processing apparatus 360 for processing. The components of advanced packaging system 300 are similar to those of advanced packaging system 100, and so, for the sake of brevity, their structure, function, and operation are not repeated herein, except insofar as may be necessary to explain how the advanced packaging systems may differ. For example, in contrast to advanced packaging system 100, advanced packaging system 300 includes a stage 330 adapted to receive a plurality of substrates and a substrate pushing unit 350 adapted to secure the plurality of substrates thereto.

In some embodiments, for instance, stage 330 may include a chuck 332 on which a plurality of substrates may be received. As illustrated in FIG. 3, for example, chuck 332 may be rectangular in form and may be adapted to receive four round substrates (e.g., a silicon wafer or glass carrier wafer). Similar to stage 130 of advanced packaging system 100, stage 330 may have a plurality of clearance holes 338 formed therethrough, which may be sized and shaped so as to accommodate a plurality of lift pins 345 therein that may be used to receive substrates on chuck 332. However, in contrast to advanced packing system 100, advanced packaging system 300 may not include clamp pins (e.g., clamp pins 141), and accurate positioning of substrates on chuck 332 may be provided during initial placement (e.g., by a robot or end effector). Furthermore, in order to accommodate the plurality of round substrates, the number and position of lift pins 345, as well as their operation, may vary.

In some embodiments, for example, lift pins 345 may operate together, to receive substrates simultaneously, while in other embodiments, they may operate to receive substrates independently. In some embodiments, for example, similar to stage 130, lift pins 345 may be coupled to (or integrally formed as part of) a (single) lift pin structure disposed within a second support body of stage 330, which may be coupled to one or more lift pin actuators 346 that may operate to move (e.g., raise and lower) the lift pin structure and lift pins 345 in the Z direction (i.e., through corresponding clearance holes 138). In this way, lifts pins 345 may operate together to simultaneously receive a plurality of substrates.

In other embodiments, lift pins 345 may be able to receive each substrate independently. For instance, as illustrated in FIG. 3, each of the four round substrates may be received using a subset of lift pins 345 (i.e., a subset of three lift pins 345). Each subset of lift pins 345 may be coupled to a separate lift pin structure 344 that may be raised and lowered (independently or collectively) by independent lift pin actuators 346.

As with stage 130, lift pins 345 may be appropriately positioned and of sufficient length to facilitate substrate transfer by a robot or end effector (e.g., providing adequate space between lift pins 345 and between top surface 333 of chuck 332 and a lower surface of a substrate that may rest there upon). The robot or end effector, for instance, may provide substrate through a e.g. (not shown) in enclosure 305 and may position substrate on raised lift pins 345 or a subset thereof (e.g., after moving one or more lift pin actuators 346 to a final position). Lift pins 345 may thereafter gently lower the substrate onto chuck 332 (e.g., by moving the lift pin actuators 346 to an initial position).

Stage 330, likewise, may include a mechanism to secure substrates thereto (e.g., to chuck 332). In some embodiments, for example, stage 330 may include a chucking mechanism (e.g., a vacuum chuck, an electrostatic chuck, or the like) that may operate to apply a downward pulling force on the substrates and secure them to chuck 332. In some embodiments, the chucking mechanism may operate to secure the substrates simultaneously, while in other embodiments, stage 330 may be able to secure each substrate independently.

In some embodiments, for example, a vacuum chucking mechanism may include a vacuum source (not shown in FIG. 3) that may be in fluid communication with one or more ports or apertures 331 formed in chuck 332. The vacuum source may operate to pull air through apertures 331, which may apply a downward pulling force on a substrate pulling it toward chuck 332 and securing it thereto. In some embodiments, the vacuum chucking mechanism may provide for different chucking zones. In some embodiments, for example, the vacuum source may be able to pull air through apertures 331 independently and may operate to pull air through a subset of one or more apertures 331 to provide different chucking zones, which may help to facilitate chucking of multiple substrates onto chuck 332. For example, as illustrated in FIG. 3, each pair of apertures 331a-d may provide for four separate chucking zones. Furthermore, each aperture in a pair of apertures 331a-d may be able to operate independently to provide an outer and inner chucking zone, which may further facilitate chucking of multiple substrates onto chuck 332.

In cases where one or more substrates exhibit a significant amount of warpage (or other variations in flatness), substrate pushing unit 350 may be used to apply a downward pushing force to help flatten the substrates so that they may be secured. Substrate pushing unit 350 may be generally similar to substrate pushing unit 150 of advanced packaging system 100 but may be adapted to apply a downward pushing force to each of the plurality of substrates.

In some embodiments, for example, substrate pushing unit 350 may be secured to support 362 of processing apparatus 360, which may provide a stable and rigid support for substrate pushing unit 350 and allow substrate pushing unit 350 to be positioned above stage 330 with minimal impact on stage accessibility (e.g., by a robot or end effector). In some embodiments, for instance, a bridge connecting plate 351 may be used to secure substrate pushing unit 350 to a bridge 163 of support 162. Bridge connecting plate 351, for instance, may be used to rigidly couple linear actuator 352 to a outer lateral surface (e.g., in the X direction) of a bridge 363 such that substrate pushing unit 350 may be disposed over stage 330 when in a load/unload position.

Linear actuator 352 may support a push assembly 370, which may be coupled thereto, and may operate to move push assembly 370 in a Z direction (e.g., relative to stage 330). Linear actuator 352 may lower push assembly 370 (e.g., from a fully raised position) when assistance with securement of a substrate is desired. Pushing assembly 370 may be used to apply a downward pushing force onto the plurality of substrates (e.g., as pushing assembly 370 is lowered by linear actuator 352).

In some embodiments, for example, substrate pushing unit 350 may include a plurality of push frames 380 corresponding to each of the plurality of substrates. Push frames 380 may have a similar shape and size as the substrates being secured, such that push frames 380 may apply a generally uniform force to the substrates. Push frames 380 may also be shaped and sized so as to generally overlap with areas of substrates that are suitable for contact and/or handling when positioned over substrates. In some embodiments, push frames 380 may include one or more cavities through which air may flow, which may help to reduce the impact that push frames 380 may have on air circulation within enclosure 305. By way of example, as illustrated in FIG. 3, push frames 380 may be generally round in form and may comprise an outer ring portion connected to a central portion by a plurality of arms. When positioned over a substrate, the outer ring portion may be disposed generally above handling and/or contact regions of the substrate.

Each of the plurality of push frames 380 may have a contact pad 386 provided thereon (e.g., integrally formed with and extending from a bottom surface thereof) that may contact a respective substrate to apply a downward pushing force thereon. Contact pads 386 may be shaped and sized so as to align with areas of substrates that are suitable for handling and/or contact. In some embodiments, for example, contact pads 386 may be relatively thin (e.g., having a thickness of 2mm) annular rings that when coupled to push frames 380 may align with a perimeter of the substrates, which may be suitable for contact and/or handling.

In some embodiments, each of the plurality of push frames 380 may be flexibly and adjustably coupled to linear actuator 352. In some embodiments, for example, the plurality of push frames 380 may be coupled to an actuator bracket 372 cantilevered over stage 330 and secured to linear actuator 352. Actuator bracket 372 may include a plurality of arms 377 that extend laterally outward (e.g., in a Y direction) such that each of the arms 377 are disposed over corresponding regions of chuck 332 where substrates may be received.

The arms 377 of actuator bracket 372 may be flexibly and adjustably coupled to a plurality of flexures 374 secured to respective push frames 380. In some embodiments, for example, each flexure 374 may be coupled to a corresponding arm 377 by a plurality of adjustment studs 376. Adjustments studs 376 may be individually and/or collectively adjusted to control an orientation (e.g., a pitch, yaw, and or roll) of a push frame 380 relative to chuck 332 of stage 330. In this way, a motion axis of each push frame 380 may be aligned perpendicular to chuck 332 so as to apply a uniform pushing force on a corresponding substrate provided thereon.

In some embodiments, flexures 374 may be secured to a top surface of a central portion of respective push frames 380 (e.g., by a plurality of screws spaced around its perimeter) and may provide for some degree of flexibility in push frame 380 relative to linear actuator 352. For example, as a push frame 380 is pushed down onto a substrate, flexure 374 may bulge or flex slightly and provide a degree of compliance in a Z direction (e.g., up to 200um). The compliance afforded by flexures 374 may help to accommodate variations in substrate warpage and/or thickness and prevent the application of excessive force to substrates.

FIGS. 4A-4C illustrate a substrate pushing unit 450 in accordance with at least one embodiment of the present disclosure. In some embodiments, substrate pushing unit 450 may serve as the substrate pushing unit 350 in the advanced packaging system 300 of FIG. 3. As illustrated, pushing unit 450 may include a linear actuator 452 supporting a pushing assembly 470 coupled thereto that may operate to move pushing assembly 470 in a Z direction. Pushing assembly 470 may include a plurality of push frames 480, having contact pads 486 provided thereon, that may be shaped and sized similar to a plurality of substrates (not shown) being secured on a stage (not shown), such that push frames 480 may apply a generally uniform force thereon.

Push frames 480 may be flexibly and adjustably coupled to linear actuator 452 using a plurality of flexures 474 and an actuator bracket 472. In some embodiments, for example, actuator bracket 472 may include a plurality of arms 477 that extend laterally outward (e.g., in a Y direction). In some embodiments, flexures 474 may be coupled to arms 477 by a plurality of adjustment studs 476. Each adjustment stud 476, for instance, may be secured at a proximal end to actuator bracket 472 and at a distal end to a flexure 474 (e.g., as shown in FIG. 4B). In some embodiments, for example, adjustment studs 476 may pass through corresponding clearance holes (or slots) provided in actuator bracket 472 and may be secured to actuator bracket 472 by a pair of nuts 490 and 492 and to flexure 474 by a pair of nuts 494 and 496. In some embodiments, a spherical float 491 may be provided between nut 490 and a top surface of base of actuator bracket 472 Adjustments studs 476 may be individually adjustable (e.g., providing adjustment in a Z direction) and/or collectively adjustable (e.g., with respect to the clearance holes) to control an orientation (e.g., a pitch, yaw, and or roll) of each push frame 480. In that regard, spherical floats 491 may provide for some amount of compliance when adjusting an orientation of the push frame.

Flexures 474 may be secured to respective push frames 480 (e.g., by a plurality of screws 475 spaced around its perimeter). In some embodiments, for example, flexures 474 may be secured to push frames 480 at a central portion 482 thereof. In some embodiments, a cavity 485 may be provided in central portion 482 of push frames 480 in order to accommodate nuts 496 below a bottom surface of flexures 474, as depicted in FIG. 4B. Flexures 474 may provide for some degree of flexibility in push frame 480 relative to linear actuator 452. For example, as a push frame 480 is pushed down onto a substrate (not shown), flexure 474 may bulge or flex slightly and provide a degree of compliance in a Z direction (e.g., up to 200 μm). The compliance afforded by flexures 474 may help to accommodate variations in substrate warpage and/or thickness and prevent the application of excessive force to a substrate.

Contact pads 486 may be coupled to each push frame 480 (e.g., integrally formed with and extending from a bottom surface thereof) and may be shaped and sized so as to align with areas of a substrate (not shown) that are suitable for handling and/or contact. In some embodiments, for example, contact pad 486 may be a relatively thin (e.g., having a thickness of 2 mm) annular ring that when coupled to push frame 480 may align with a perimeter of substrate, which may be suitable for contact and/or handling. A portion of contact pad 486 may extend from a bottom surface of push frame 480 and establish a bottom surface that may be brought into contact with a substrate (e.g., in regions suitable for handling and/or contact.

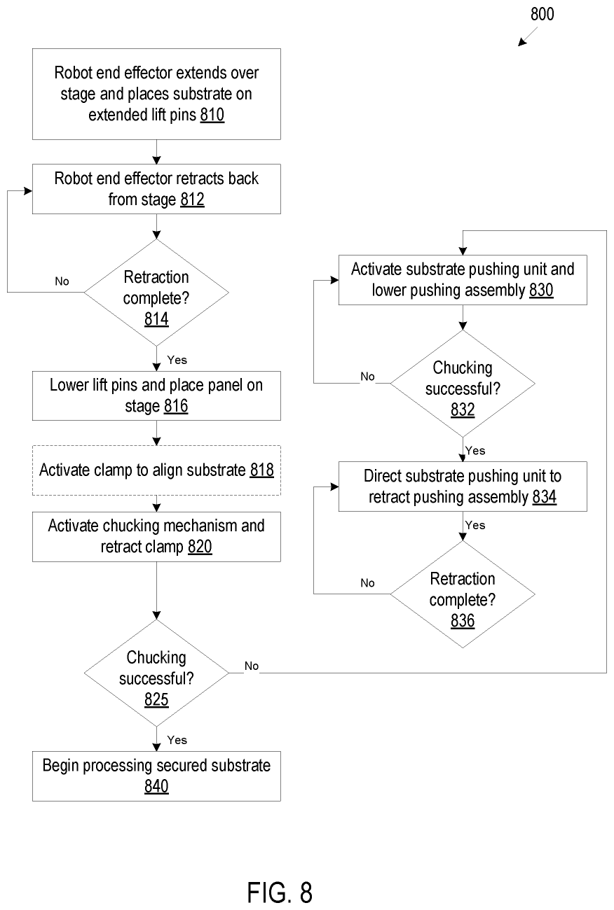

FIG. 8 illustrates a flow diagram of an example method 800 for receiving and securing a substrate to a stage for processing in accordance with at least one embodiment of the present disclosure. For the sake of simplicity and clarity, the method is depicted and described as a series of operations. However, in accordance with the present disclosure, such operations may be performed in other orders and/or concurrently, and with other operations not presented or described herein. Furthermore, not all illustrated operations may be required in implementing methods in accordance with the present disclosure. Those of skill in the art will also understand and appreciate that the methods could be represented as a series of interrelated states or events via a state diagram. Additionally, it will be appreciated that the disclosed methods are capable of being stored on an article of manufacture. The term “article of manufacture,” as used herein, is intended to encompass a computer-readable device or storage media provided with a computer program and/or executable instructions that, when executed, affect one or more operations. The method 800 (or portions thereof) may be performed by processing logic of a computing device (e.g., using a controller of the advanced packaging system 100 of FIG. 1 or advanced packaging system 300 of FIG. 3).

At operation 810, a stage of an advanced packaging system may be in a home position and have a plurality of lift pins in a raised position above a chuck. A robot or end effector may extend over the stage and place one or more substrates on the raised lift pins of the stage. Once the substrate(s) have been placed on the lift pins, the robot or end effector may begin to retract, at operation 812. At operation 814, the advanced packaging system may monitor a position of the robot or end effector and wait until the robot or end effector is fully retracted and/or clear of the stage.

At operation 816, after the robot or end effector has been fully retracted and/or is clear of the stage, the lift pins may retract from their raised position to a recessed position and the substrate(s) may be gently placed onto a chuck of the stage.

At operation 818, a clamp may be activated to align the substrate(s) in a desired position. In some embodiments, for example, a plurality of clamp pins may rise (in the Z direction) from a recessed position to a raised position above the stage surface. The clamp pins may then move medially from an initial outer position to a final inner position, aligning substrate(s) to a desired position on the chuck in the process. In some embodiments, air may be pushed out through a plurality of apertures in the chuck, which may operate to lift (or float) the substrate(s), thereby reducing the amount of interaction between the substrate(s) and chuck as the substrate(s) are being aligned. It will be appreciated that operation 818 may be optional, and in some embodiments, accurate positioning of the substrate(s) may be provided during initial placement (e.g., by a robot or end effector).

At operation 820, a chucking mechanism may be activated to secure the substrate(s) to the chuck. In some embodiments, for example, a vacuum chuck may be activated, which may pull air through a plurality of apertures resulting in a downward pulling force on the substrate(s). Once initiated, clamp pins that may have been activated at operation 818 may be lowered (in the Z direction) back to an initial recessed position.

At operation 825, a determination may be made as to whether the substrate(s) have been successfully secured. In some embodiments, for example, feedback provided by the chucking mechanism may be monitored to detect if and/or when the substrate(s) have been secured. For instance, in embodiments where a vacuum chuck is used, air flow rate or vacuum pressure feedback provided by a vacuum chuck may be monitored. If the air flow rate or vacuum pressure drops (e.g., below a threshold amount), a determination may be made that the substrate(s) have been successfully secured and the method 800 may proceed to operation 840. If the air flow rate or vacuum pressure remains elevated (e.g., above a threshold amount and/or for longer than a minimum duration), a determination may be made that the substrate(s) are significantly warped and that assistance may be needed from a substrate pushing unit, and the method 800 may proceed to operation 830.

At operation 830, a substrate pushing unit may be activated and may begin to lower a pushing assembly of the pushing unit (e.g., from a fully raised position) down toward the chuck of the stage. As the pushing assembly is lowered, it may be brought into contact with and apply a downward pushing force onto the substrate(s).

At operation 832, upon activation of the substrate pushing unit, feedback provided by the chucking mechanism may be continuously monitored to detect if and/or when the substrate has been secured. For instance, in embodiments where a vacuum chuck is used, air flow rate or vacuum pressure feedback provided by a vacuum chuck may be continuously monitored, for example, to detect when the air flow rate or vacuum pressure drops, in which case a determination may be made that the substrate(s) have been successfully secured. Operation 830 may continue (i.e., the pushing assembly may continue to be lowered) until such a determination is made.

At operation 834, upon a determination that the substrate(s) have been successfully secured, the substrate pushing unit may be directed to retract the pushing assembly back to a fully raised position and the pushing assembly may begin to be raised. At operation 836, upon direction of the substrate pushing unit to begin retracting the pushing assembly, a position of the substrate pushing assembly may be continuously monitored to detect when the substrate pushing assembly has reached its fully raised position. Operation 834 may continue (i.e., the pushing assembly may continue to be raised) until such a determination is made. Upon making a determination that that the substrate pushing assembly has been fully raised, the method 800 may return to operation 825.

At operation 840, upon making a determination that the substrate(s) have been successfully secured, processing of the secured substrate may begin, and the stage may start to move toward a processing apparatus.

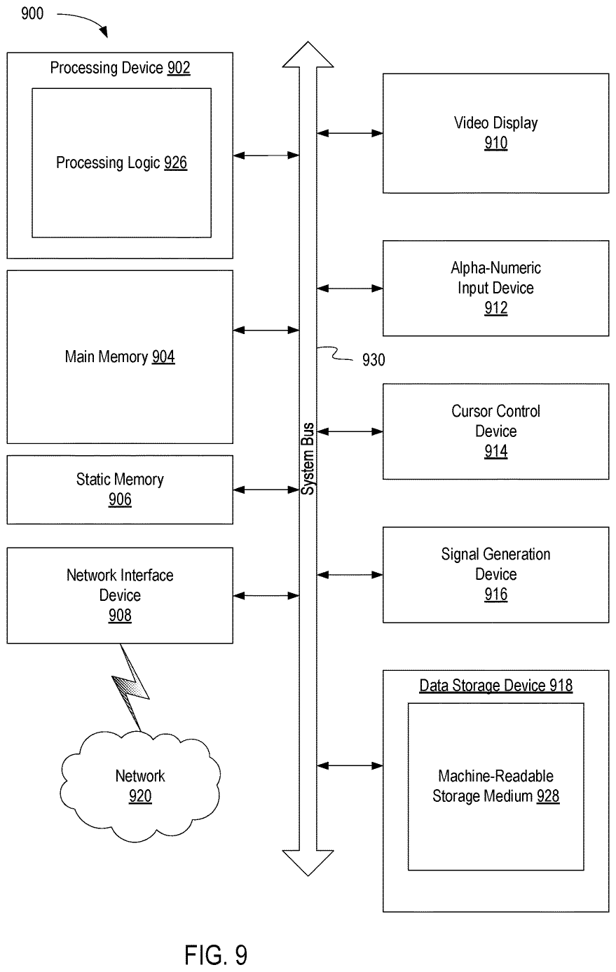

FIG. 9 illustrates a block diagram of an example computer system 900 in accordance with at least one embodiment of the present disclosure. The computer system 900 may include a set of executable instructions to perform one or more of the methodologies discussed herein. In one embodiment, for example, the computer system 900 may include instructions to enable execution of the processes and corresponding components shown and described in connection with FIGS. 1-4.

In alternative embodiments, the systems may include a machine connected (e.g., networked) to other machines in a LAN, an intranet, an extranet, or the Internet. The machine may operate in the capacity of a server machine in client-server network environment. The machine may be a personal computer (PC), a neural computer, a set-top box (STB), Personal Digital Assistant (PDA), a cellular telephone, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies described herein.

The example computer system 900 can include a processing device (processor) 902, a main memory 904 (e.g., read-only memory (ROM), flash memory, dynamic random access memory (DRAM) such as synchronous DRAM (SDRAM)), a static memory 906 (e.g., flash memory, static random access memory (SRAM)), and a data object storage device 918, which communicate with each other via a bus 930.

Processing device 902 represents one or more general-purpose processing devices such as a microprocessor, central processing unit, or the like. More particularly, the processing device 902 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 902 may also be one or more special-purpose processing devices such as an application specific integrated circuit (ASIC), a field programmable gate array (FPGA), a digital signal processor (DSP), network processor, or the like. In various embodiments of the present disclosure, the processing device 902 is configured to execute instructions for the devices or systems described herein for performing the operations and processes described herein.

The computer system 900 may further include a network interface device 908. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), and a signal generation device 916 (e.g., a speaker).

The data storage device 918 may include a computer-readable medium 928 on which is stored one or more sets of instructions of the devices and systems as described herein embodying any one or more of the methodologies or functions described herein. The instructions may also reside, completely or at least partially, within the main memory 904 and/or within processing logic 926 of the processing device 902 during execution thereof by the computer system 900, the main memory 904 and the processing device 902 also constituting computer-readable media.

The instructions may further be transmitted or received over a network 920 via the network interface device 908. While the computer-readable storage medium 928 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing, encoding or carrying a set of instructions for execution by the machine and that cause the machine to perform any one or more of the methodologies of the present disclosure. The term “computer-readable storage medium” shall accordingly be taken to include, but not be limited to, solid-state memories, optical media, and magnetic media.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a substrate positioned on a movable stage; and
a substrate pushing unit comprising:
a linear actuator adapted to lower a pushing assembly onto the substrate and apply a downward force to flatten the substrate.

2. The system of claim 1 further comprising a vacuum chuck for securing the substrate to the movable stage, wherein the linear actuator lowers the pushing assembly onto the substrate based on a determination that the vacuum chuck alone is unable to secure the substrate to the movable stage.

3. The system of claim 1 wherein the pushing assembly comprises a push frame having a contact pad provided thereon, wherein the contact pad is brought into contact with a top surface of the substrate as the pushing assembly is lowered.

4. The system of claim 3 wherein the contact pad is adapted to contact an exclusion area of the substrate suitable for contact.

5. The system of claim 3 wherein an orientation of the push frame is adjustable relative to the substrate.

6. The system of claim 5 wherein the pushing assembly comprises an actuator bracket attached to the linear actuator and the push frame is coupled to the actuator bracket by one or more adjustment studs that allow for adjustment of the orientation of the push frame.

7. The system of claim 3 wherein the push frame is flexibly coupled to the linear actuator.

8. The system of claim 7 wherein the push frame is coupled to the linear actuator by a flexure that provides flexibility in a Z direction when applying the downward force to flatten the substrate.

9. An apparatus comprising:
a pushing assembly; and
a linear actuator adapted to lower the pushing assembly onto a substrate positioned on a movable stage and apply a downward force to flatten the substrate.

10. The apparatus of claim 9 wherein the linear actuator lowers the pushing assembly onto the substrate based on a determination that a vacuum chuck alone is unable to secure the substrate to the movable stage.

11. The apparatus of claim 9 wherein the pushing assembly comprises a push frame having a contact pad provided thereon, wherein the contact pad is brought into contact with a top surface of the substrate as the pushing assembly is lowered.

12. The apparatus of claim 11 wherein the contact pad is adapted to contact a portion of the top surface suitable for contact.

13. The apparatus of claim 11 wherein an orientation of the push frame is adjustable relative to the substrate.

14. The apparatus of claim 13 wherein the pushing assembly comprises an actuator bracket attached to the linear actuator and the push frame is coupled to the actuator bracket by one or more adjustment studs that allow for adjustment of the orientation of the push frame.

15. The apparatus of claim 11 wherein the push frame is flexibly coupled to the linear actuator.

16. The apparatus of claim 15 wherein the push frame is coupled to the linear actuator by a flexure that provides flexibility in a Z direction when applying the downward force to flatten the substrate.

17. A method comprising:
receiving a substrate on a movable stage; and
using a linear actuator to lower a pushing assembly onto the substrate and apply a downward force to flatten the substrate.

18. The method of claim 15 further comprising:
lowering the pushing assembly onto the substrate based on a determination that a vacuum chucking mechanism alone is unable to secure the substrate to the movable stage.

19. The method of claim 15 wherein the pushing assembly comprises a push frame having a contact pad provided thereon, wherein the contact pad is brought into contact with a top surface of the substrate as the pushing assembly is lowered.

20. The method of claim 17 wherein the contact pad is adapted to contact a portion of the top surface of the substrate suitable for contact.

21. The method of claim 17 further comprising:
adjusting an orientation of the push frame relative to the substrate.

22. The method of claim 17 wherein the push frame is flexibly coupled to the linear actuator.
